(19) United States
(12) Patent Application Publication
(10) Pub. No.: US 2012/0146142 A1
(43) Pub. Date: Jun. 14, 2012

(54) MOS TRANSISTOR AND METHOD FOR MANUFACTURING THE SAME

(75) Inventors: Huilong Zhu, Poughkeepsie, NY (US); Haizhou Yin, Poughkeepsie, NY (US); Zhijiong Luo, Poughkeepsie, NY (US)

(73) Assignee: Institute of Microelectronics, Chinese Acaademy of Sciences, Beijing (CN)

(21) Appl. No.: 13/148,994

(22) PCT Filed: Feb. 24, 2011
(86) PCT No.: PCT/CN2011/071263

§ 371 Date: Aug. 11, 2011

(30) Foreign Application Priority Data
Dec. 14, 2010 (CN) 201010587887.0

(51) Int. Cl. H01L 27/12; H01L 21/84

(52) U.S. Cl. 257/347; 438/151; 257/E27.112; 257/E21.703

(57) ABSTRACT

The present invention provides a MOS transistor and a method for manufacturing the same. The MOS transistor includes: a SOI substrate comprising a silicon substrate layer, an ultra-thin BOX layer, and an ultra-thin SOI layer; a metal gate layer formed on the SOI substrate; and a ground halo region formed in the silicon substrate layer and beneath the metal gate layer. The method for manufacturing a MOS transistor comprises: providing a SOI substrate, which comprises a silicon substrate layer, an ultra-thin BOX layer, and an ultra-thin SOI layer: forming a dummy gate conductive layer on the SOI substrate and a plurality of spacers surrounding the dummy gate conductive layer, removing the dummy gate conductive layer to form a opening; performing an ion-implantation process in the opening to form a ground halo region in the silicon substrate layer; and forming a metal gate layer in the opening.

### CROSS REFERENCE TO RELATED APPLICATIONS

The present application is a Section 371 National Stage Application of, and claims the priority to, International Application No. PCT/CN2011/071263, filed on Feb. 24, 2011, which claimed the priority of Chinese Patent Application No. 201010587887.0, and filed on Dec. 14, 2010. The entire contents of the international application and the Chinese application are incorporated herein by reference in their entireties.

### FIELD OF THE INVENTION

The present invention is related to semiconductor manufacturing technology, and especially, to a MOS transistor and a method for manufacturing the same.

### BACKGROUND OF THE INVENTION

For Complementary Metal Oxide Semiconductor (CMOS) devices, a halo implantation process is always performed to suppress short channel effects (SCE). However, as the CMOS devices scaling down to small sizes continuously, the angel of halo implantation is restricted by the pattern. For example, in CMOS technology, pitch between adjacent devices has become very small, however, the thickness of photoresist which is used as a halo implantation mask fails to scale down with the devices, resulting in a shadowing effect. As a result, high implantation energy and large implantation dose are necessary in order to perform doping at predetermined positions. Thus, it is very difficult to perform a conventional halo implantation process with a large angle.

In order to resolve this problem, Zhibin Ren etc. disclosed a Ground Plane technique in “Selective Epitaxial Channel Ground Plane Thin SOI CMOS Devices, IEEE 2005”. Compared with conventional large angel halo implantation, dopants are implanted in zero angel in Ground Plane technique, thus the restriction caused by the pattern in halo implantation has been overcome, and at the same time, the dopants plays a role in suppressing short channel effects. Referring to FIGS. 1A and 1B, wherein reference number 10 is a substrate, 12 is a source/drain region, 14 is a gate, 16 is a halo, and 18 is a ground plane.

Ground Plane technique can be applied in both CMOS transistors and Silicon On Insulator (SOI) CMOS transistors. However, for SOI CMOS transistors, drawback of Ground Plane technique is in that it will increase the capacitance between the SOI and the substrate, and thus it will probably reduce the AC characteristic of MOS field effect transistors.

### SUMMARY OF THE INVENTION

One object of embodiments of the present invention is to provide a MOS transistor and a method for manufacturing the same to suppress short channel effects, and at the same time, to reduce the capacitance between the SOI and the substrate and avoid affecting the alternating current characteristic of MOS transistors.

To achieve the object, it is provided in one embodiment of the present invention a MOS transistor, comprising:

an SOI substrate, which comprises a silicon substrate layer, an ultra-thin BOX layer, and an ultra-thin SOI layer;

a metal gate layer formed on the SOI substrate; and

a ground halo region, which is formed in the silicon substrate layer and beneath the metal gate layer.

Optionally, the ultra-thin SOI layer has a thickness in the range of 3-20 nm and the ultra-thin BOX layer has a thickness in the range of 2-15 nm.

Optionally, the MOS transistor further comprises a high-K dielectric layer formed between the metal gate layer and the ultra-thin SOI layer.

Optionally, for an n-type MOS transistor, the ground halo region comprises p-type dopants, and for a p-type MOS transistor, the ground halo region comprises n-type dopants.

Optionally, the ground halo region has a doping concentration of 1×10¹⁷-3×10¹⁹/cm³.

Optionally, the MOS transistor further comprises a raised source region and a raised drain region, which are formed on the ultra-thin SOI layer, and at both sides of the metal gate respectively.

Optionally, for a p-type MOS transistor, the raised source region and the raised drain region comprise a SiGe layer, and for an n-type MOS transistor, the raised source region and the raised drain region comprise a Si:C layer.

Optionally, for the Si:C layer, the atomic percentage of C is 0.5-2%, and for the SiGe layer, the atomic percentage of Ge is 20-70%.

Optionally, for an n-type MOS transistor, the Si:C layer further comprises n-type dopants, and for a p-type MOS transistors, the SiGe layer further comprises p-type dopants.

Optionally, the p-type dopants comprise B, In or a combination thereof; and the n-type dopants comprise As, P or a combination thereof.

In another embodiment, it is provided a method for manufacturing a MOS transistor, comprising;

providing an SOI substrate, the SOI substrate having a silicon substrate layer, an ultra-thin BOX layer and an ultra-thin SOI layer;

forming a dummy gate conductive layer and a plurality of spacers, the plurality of spacers surrounding the dummy gate conductive layer on the SOI substrate;

removing the dummy conductive layer to form a opening; performing an ion implantation process in the opening to form a ground halo region in the silicon substrate; and

forming a metal gate layer in the opening.

Optionally, the ultra-thin SOI layer has a thickness in the range of 3-20 nm and the ultra-thin BOX layer has a thickness in the range of 2-15 nm.

Optionally, the method further comprises forming a high-K dielectric layer in the opening before the metal gate layer is formed.

Optionally, the method further comprises performing an annealing process after the ground halo region is formed.

Optionally, during the step of forming the ground halo region, the ion implantation process is performed with p-type dopants for an n-type MOS transistor, and with n-type dopants for a p-type MOS transistor.

Optionally, the ground halo region has a doping concentration of 1×10¹⁷-3×10¹⁹/cm³.

Optionally, the method further comprises forming a raised source region and a raised drain region through a selective epitaxial growth process after the dummy gate conductive layer and the spacers are formed.

Optionally, during the selective epitaxial growth process, a SiGe layer is formed for a p-type MOS transistor, and a Si:C layer is formed for an n-type MOS transistor.

Optionally, for the Si:C layer, the atomic percentage of C is 0.5-2%, and for the SiGe layer, the atomic percentage of Ge is 20-70%.

Optionally, an in-situ doping process is performed with n-type dopants for an n-type MOS transistor, and with p-type dopants for a p-type MOS transistor.

Optionally, the p-type dopants comprise B, In, or a combination thereof, and the n-type dopants comprises As, P, or a combination thereof.

The MOS transistor according to the embodiment of the present invention can suppress short channel effects and at the same time avoid increasing the capacitance between the ultra-thin SOI layer and the substrate, and thus the influence to the alternating current characteristic of the MOS transistors can be reduced.

### BRIEF DESCRIPTION OF THE DRAWINGS

The accompanying drawings, which are incorporated herein and form a part of the specification, and together with the description, further serve to explain the principles of the embodiments of the invention and to enable a person skilled in the art to make and use the invention. It is noted that the drawings are provided for illustrative purposes only and, as such, they are not drawn to scale.

FIGS. 1A and 1B are schematic views of MOS transistors in the prior art;

FIG. 2 is a schematic view of a MOS transistor according to an embodiment of the present invention; and

FIGS. 3 to 15 are schematic cross-sectional views of intermediate structures of a MOS transistor according to the embodiment of the present invention.

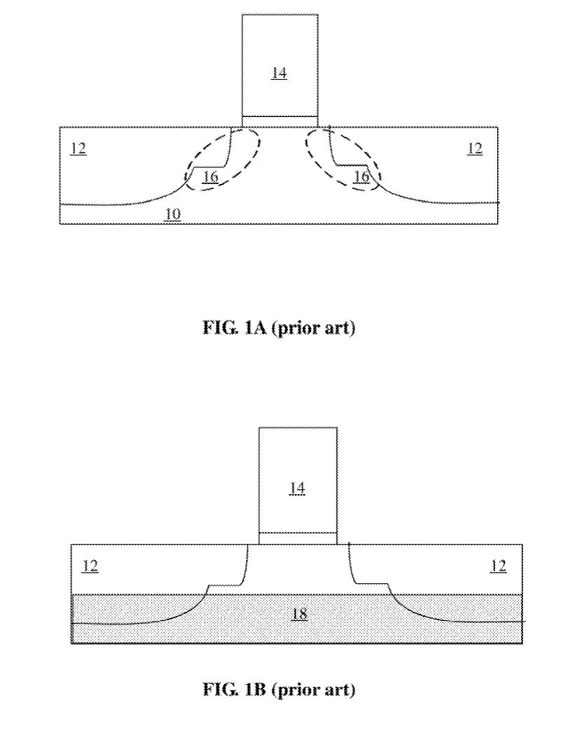

### DETAILED DESCRIPTION OF THE EMBODIMENTS

Although the present invention has been disclosed hereinafter as above with reference to preferred embodiments in details to make it be fully understood, the present invention can be implemented in other embodiments which are different. Those skilled in the art can make similar deduction without departing from the scope of the present invention. Therefore, the present invention should not be limited to the embodiments disclosed hereunder.

### Embodiment 1

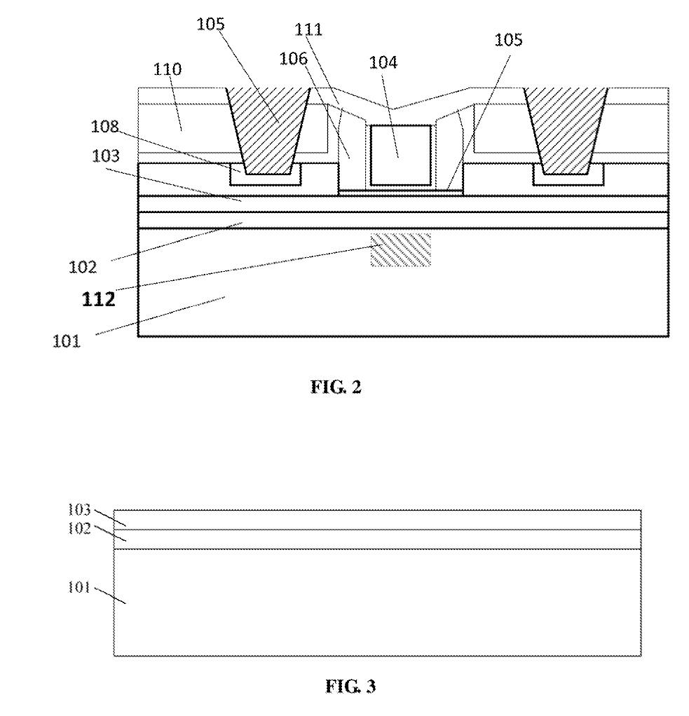

FIG. 2 is a schematic view of a MOS transistor according to an embodiment of the present invention. Referring to FIG. 2, the MOS transistor of the embodiment includes a SOI substrate, wherein the SOI substrate comprises a silicon substrate 101, an ultra-thin BOX layer 102, and an ultra-thin SOI layer 103; a metal gate layer 104 formed on the SOI substrate; and a ground halo region 112 formed in the silicon substrate layer 101 and beneath the metal gate layer 104.

The SOI substrate has a very small parasitic capacitance and is free from latch effect because of the existence of the ultra-thin BOX layer 102. The effect of charge coupling may be further enhanced by the ultra-thin BOX layer 102. The ultra-thin SOI layer 103 may be made of a very thin semiconductor material, such as Si, to fully deplete the semiconductor film to form an inversion layer, and thus the mobility of carriers can be increased and short channel effects can be well suppressed.

The ground halo region is formed in the silicon substrate 101 further. The ground halo region 112 is used to suppress short channel effects. Compared with the prior art which uses a ground plane beneath the ultra-thin BOX layer 102 to suppress short channel effects, a ground halo region 112 is used to suppress short channel effects in the embodiment of the present invention. Since the ground halo region 112 is smaller in area, capacitance between the ultra-thin SOI layer 103 and the ultra-thin BOX 102 can be reduced, thus influence to the alternating current characteristic of MOS transistor can be diminished.

Further, a high-K dielectric layer 113 is formed between the metal gate layer 104 and the ultra-thin SOI layer 103. The high-K dielectric layer 113 is mainly used to reduce the gate leakage.

### Embodiment 2

The embodiment of the present invention further provides a method for manufacturing a MOS transistor, and FIGS. 3 to 15 are schematic cross-sectional views of intermediate structures of a MOS transistor according to the embodiment of the present invention.

FIG. 3 is an intermediate structure obtained in the method for manufacturing a MOS transistor according to the embodiment of the invention.

Referring to FIG. 3, an ultra-thin SOI substrate is provided. The ultra-thin SOI substrate may include a silicon substrate layer 101, an ultra-thin BOX layer 102 formed on the silicon substrate layer 101, and an ultra-thin SOI layer 103 formed on the ultra-thin BOX layer 102.

Optionally, the ultra-thin BOX layer 102 may has a thickness in the range of 2-15 nm, and the ultra-thin SOI layer 103 may has a thickness in the range of 3-20 nm. The ultra-thin SOI layer may be made of Si, Ge, Si:C, or III-V compounds. A source region and a drain region (not shown in the figures) may be formed within the ultra-thin SOI layer 103 according to a conventional method such as an ion implantation process.

The SOI substrate has very small parasitic capacitances and is free from latch effect because of the existence of the ultra-thin BOX layer 102. Coupling effect of charges can be further enhanced by the ultra-thin BOX layer 102.

Further, the ultra-thin SOI layer 103 may be made of a very thin semiconductor material, such as Si, and thus the semiconductor film can be fully depleted, an inversion layer can be achieved, mobility of carriers can be increased, and short channel effects can be well suppressed.

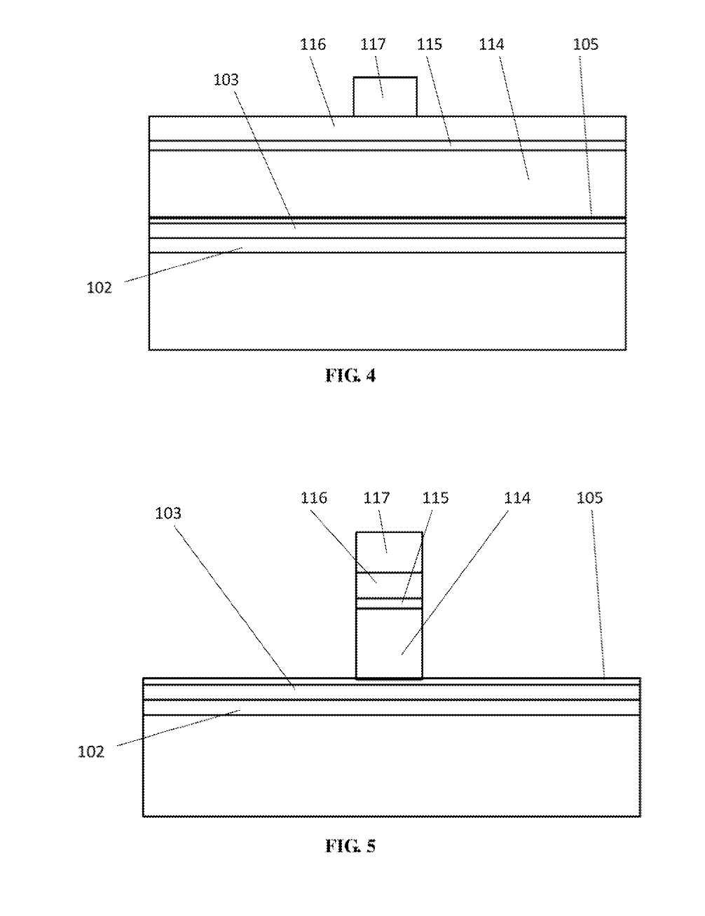

FIGS. 4 to 6 are schematic cross-sectional views of intermediate structures obtained in the method for manufacturing a MOS transistor according to the embodiment of the invention.

A gate oxide layer 105 (for example, silicon oxide or silicon oxynitride), a dummy gate conductive layer 114 (for example, a polysilicon layer), a first etching protection layer 115 (for example, silicon oxide), and a protection cap layer 116 (for example, silicon nitride) are formed on the ultra-thin SOI layer 103 sequentially, and the obtained intermediate structures formed are patterned.

Layers mentioned above may be formed through a conventional deposition process, such as physical vapor deposition (PVD), chemical vapor deposition (CVD), atomic layer deposition (ALD), pulsed laser deposition (PLD), metal organic chemical vapor deposition (MOCVD), plasma enhanced atomic layer deposition (PEALD), plasma enhanced chemical vapor deposition (PECVD), sputtering, molecular beam epitaxy (MBE), and so on.

Here, the dummy gate conductive layer 114 may be free of being effected during the subsequent etching processes since it is protected by the first etching protection layer 115. During the subsequent epitaxial growth process, the protection cap layer 116 is used to avoid any undesired epitaxial growth on the top surface of the dummy gate conductive layer 114.

Then, a patterned photoresist layer 117 is formed on the protection cap layer 116. The position of the photoresist layer 117 is corresponding to the gate which will be formed later.

The patterned photoresist layer 117 may be formed by the following steps: firstly, a photoresist layer (not shown in the figures) is coated on the protection cap layer 116 in a spin coating process, then the coated photoresist layer is softly baked; then, the photoresist layer is exposed and developed; and the patterned photoresist layer 117 is formed. Afterward, the portions of the layers in both sides of the patterned photoresist layer 117 are etched using the patterned photo-resist layer 117 as a mask, until the gate oxide layer is exposed. A reaction ion etching (RIE) method may be used in the above-mentioned etching process. An intermediate structure formed is shown in FIG. 5.

Referring to FIG. 6, the patterned photoresist layer 117 is removed, and a plurality of spacers 106, which surround the dummy gate conductive layer 114, the first etching protection layer 115, and the protection cap layer 116, are formed. The spacers 116 may be used as a mask and/or as an etching protection layer in the following steps. Referring to the intermediate structure shown in FIG. 6, the top surface of the dummy gate conductive layer 114 is covered by the first etching protection layer 115 and the protection cap layer 160 and surrounded by the spacers 116.

A photoresist lift off process may be performed to remove the patterned photoresist layer 117. In an embodiment, a wet process is used. Of course, a photoresist remove process with plasma may also be used, which removes the photoresist layer in a dry process with oxygen.

A halo implantation process or an extension implantation process may be performed in the ultra-thin SOI layer 103 according to the requirement, wherein n-type dopants such as As, P, or a combination thereof may be used for an extension implantation process for an n-type MOS transistor, and p-type dopants such as B, BF₂, In, or a combination thereof may be used for an extension implantation process for a p-type MOS transistor.

Optionally, the type of the dopants used in the halo implantation process is opposite to that of the dopants used in the extension implantation process. For example, p-type dopants such as B, BF₂, In or a combination thereof may be used in the halo implantation process for an n-type MOS transistor and n-type dopants such as As, P, or a combination thereof may be used in the halo implantation process for a p-type MOS transistor.

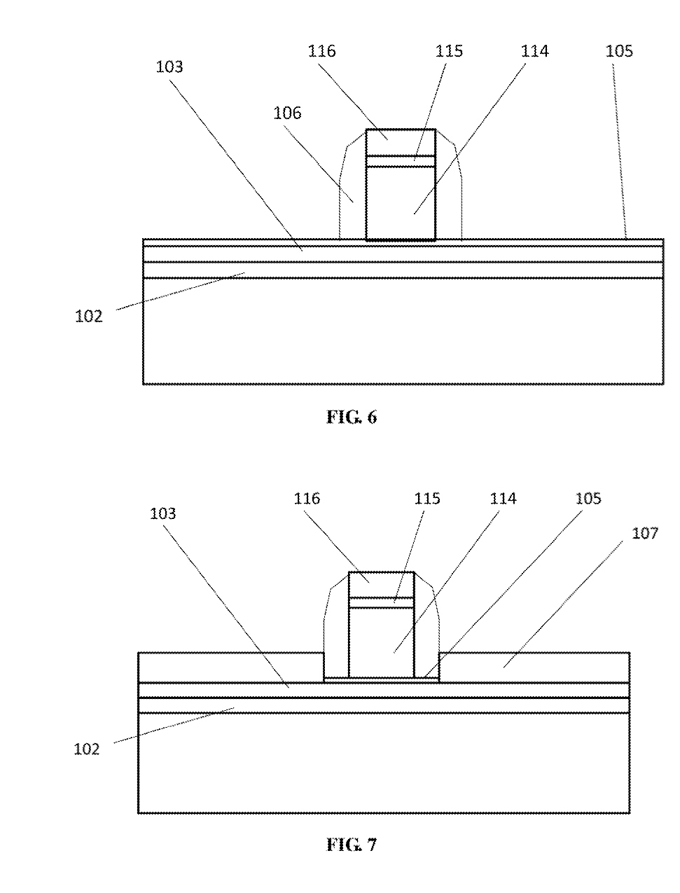

Referring to FIG. 7, the gate oxide layer 105 is etched by using the protection cap layer 116 and the spacers 106 as a mask. The dummy gate conductive layer 114 and the gate oxide layer 105 beneath the spacers 106 are remained.

Then, optionally, a source/drain region 107 may be formed to reduce serial resistance of the source region and the drain region according to an embodiment of the present invention. For example, a selective epitaxial growth process may be performed on the ultra-thin SOI layer by using the protection cap layer 116 and the spacers 106 as a mask. Materials used in the selective epitaxial growth process may comprise SiGe for a p-type MOS transistor to generate compressive stress, and Si:C for an n-type MOS transistor to generate tensile stress.

Of course, those skilled in the art would know that a conventional method may also be applicable, which comprises steps such as photoresist coating, photolithography, and etching may be performed to form groove regions with predetermined sizes at predetermined positions in the ultra-thin SOI layer 103. Then the epitaxial growth process may be performed in the groove regions.

Optionally, an in-situ doping process may be performed when the raised source/drain region 107 is formed during the optional epitaxial growth process. For example, n-type dopants such as As and/or P may be used in the in-situ doping process for an n-type MOS transistor, and p-type dopants such as B, and/or In may be used in the in-situ doping process for a p-type MOS transistor. Optionally, an annealing process such as a laser annealing process may be performed to activate the dopants. Thus, regions of opposite doping types are formed respectively beneath the source/drain regions 107 and the gate conductive layer 114, and inside the ultra thin SOI layer 103.

Of course, the raised source/drain region 107 may be formed through the above-mentioned deposition methods.

In this case, a SiGe layer may be formed for a p-type MOS transistor during the selective epitaxial growth process, wherein the atomic percentage of Ge is 20-70%; and a Si:C layer may be formed for an n-type MOS transistor, wherein the atomic percentage of Ge is 0.5-2%.

Referring to FIG. 8, a CMP stop layer 118 (for example, nitride) and an interlayer dielectric layer 110 (for example, oxide) are formed. A chemical mechanical planarization (CMP) process is performed and stops at the CMP stop layer 118. The interlayer dielectric layer 110 is etched-back.

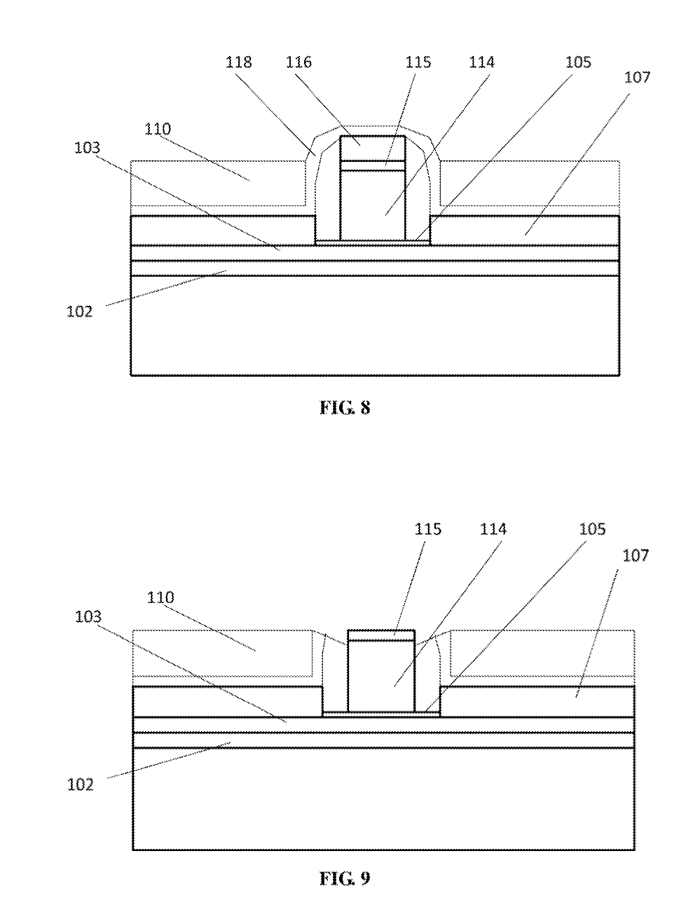

Referring to FIG. 9, the CMP stop layer 118 and the protection cap layer 116 are removed through etching (for example, a reactive ion etching process), until the first etching protection layer 115 is exposed.

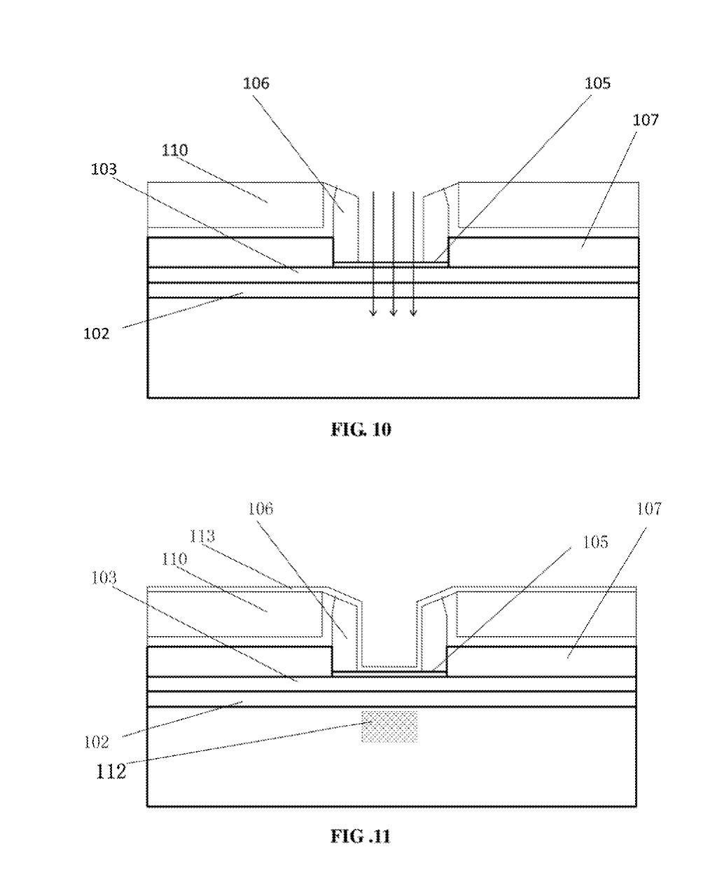

Referring to FIG. 10, the first etching protection layer 115 is removed through etching, for example, through a reactive ion etching process. Thereafter, the dummy gate conductive layer 114 is removed by further etching, until an opening is formed and the gate oxide layer 105 is exposed.

Thereafter, by using the interlayer dielectric layer 110, the CMP stop layer 118, and the spacers 106 as a mask, an ion-implantation process, which is along the direction of the arrows (shown in FIG. 10), is performed in the portion of the ultra-thin SOI substrate beneath the dummy gate conductive layer 114, in order to form a ground halo region 112 shown in FIG. 11.

The ground halo region 112 is used to suppress short channel effects. In the prior art, a ground plane beneath the ultra-thin BOX layer 102 is applied to suppress short channel effects. In the embodiment of the present invention, since the ground halo region 112 has a smaller area, the capacitance between the ultra-thin SOI layer 103 and the ultra-thin BOX 102 is reduced, and thus, influence to the alternating current characteristic of MOS transistors is reduced.

In this case, for an n-type MOS transistor, the implantation process may be performed with p-type dopants such as B, BF2 and/or In, which have a doping concentration of 1×10¹⁷-3×10¹⁹/cm³. For a p-type MOS transistor, the implantation process may be performed with n-type dopants such as As and/or P, which have a doping concentration of 1×10¹⁷-3×10¹⁹/cm³.

Optionally, an annealing process is performed after performing the implantation process in the ground halo region. Preferably, a rapid thermal annealing process (RTA, at 1050 □), for example, a spike annealing process or a laser annealing process, is performed to activate the dopants and to repair defects inside the semiconductor material and on the surface of the semiconductor material. At the same time, because the rapid thermal annealing process lasts for a short time, for example, millisecond-level-long or even shorter time, undesired doping diffusion can be avoided, and the profile of dopant concentration can be steep.

Of course, the annealing after the in-situ doping process may be unnecessary. The annealing process may not be performed until the ground halo region is implanted. In this case, only one annealing process is needed to activate the dopants as well as those in the extension region and in the halo region (if any).

Referring to FIG. 11, a high-K dielectric layer 113 is formed (for example, through a deposition process). The high-K dielectric layer may be made of HfO₂, HfSiO, HfSiON, HfTaO, HfTiO, HfZrO, Al₂O₃, La₂O₃, ZrO₂, LaAlO, and so on. The high-K dielectric layer 113 has a thickness in the range of 1-3 nm. The high-K dielectric layer 113 is used as a gate dielectric layer in the embodiment.

As MOS transistors scaling down to small sizes continuously, compared with a traditional gate dielectric layer such as silicon oxide, the high-K dielectric layer 113 can have a smaller equivalent oxide thickness (EOT) without deteriorating gate leakage, which improves the performance and the reliability of MOS transistors.

It should be noted that if the high-K dielectric layer 113 needs to be formed under a high temperature, the high-K dielectric layer 113 may be deposited before the ion-implantation process for the ground halo region to avoid undesired doping diffusion as much as possible.

Optionally, an annealing process may be performed after the high-K dielectric layer 113 is deposited, so as to reduce the defects in the high-K dielectric material and improve the quality of the high-K dielectric material layer, and thus the performance and the reliability of the devices can be improved.

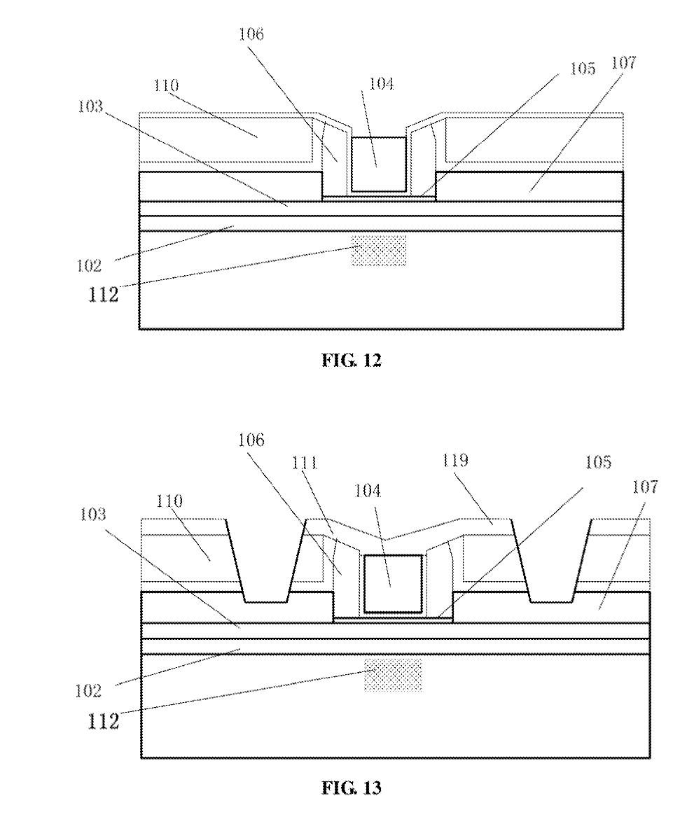

Referring to FIG. 12, a metal gate layer 104 is formed. In an embodiment, metal gate material may be deposited (for example, by CVD) on the structure shown in FIG. 10, and then an etch-back process is performed to form the structure shown in FIG. 11.

Optionally, the metal gate layer 104 may comprise work function metal material. For example, for an n-type MOS transistor, the metal gate layer may be made of TaC, TiN, TaTbN, TaErN, TaYbN, TaSiN, HfSiN, MoSiN, RuTax, and NiTax, or a combination thereof. For a p-type MOS transistor, the metal gate layer may be made of MoNx, TaSiN, TiCN, TaAIC, TiAIN, TaN, PtSix, Ni3Si, Pt, Ru, Ir, Mo, HfRu, and RuOx, or a combination thereof.

Referring to FIGS. 13-15, a contact via and a silicide layer are formed on the semiconductor structure shown in FIG. 11 with conventional processes.

Referring to FIG. 13, a second etching protection layer 119 is formed on the whole semiconductor structure. Optionally, the second etching protection layer 119 is formed through a deposition process. The second etching protection layer 119 comprises silicon nitride, and has a thickness in the range of 10-20 nm.

Referring to FIG. 13, optionally, a mask (for example, photoresist) is formed on the semiconductor structure having the second etching protection layer. Then, the mask is patterned and etched to form contact vias at predetermined positions on the interlayer dielectric layer 110. The contact vias extend through the second etching protection layer 119, the interlayer dielectric layer 110, and the CMP stop layer 118. The source/drain regions 107 are exposed at the bottom of the contact vias.

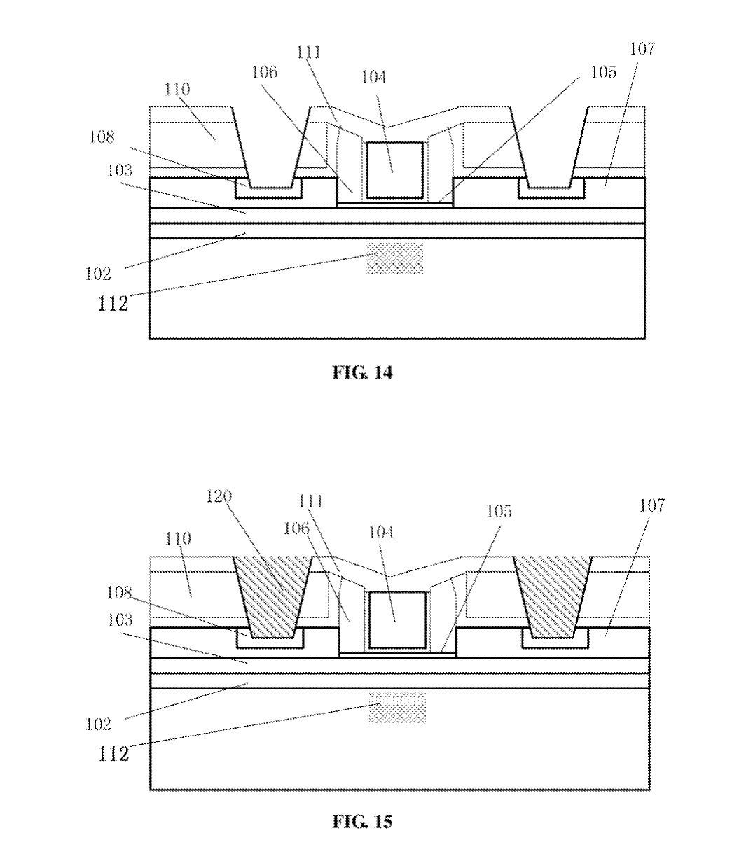

Referring to FIG. 14, a metal layer is formed, which fills the contact vias and covers the second etching protection layer 119. Optionally, the metal layer is formed through a deposition process. Optionally, the metal layer comprises NiPt and has a thickness in the range of 3-15 nm.

Then, an annealing process is performed to make the metal layer filled in the contact vias react with the SiGe beneath the metal layer, so as to form a silicide layer 108. Optionally, the annealing process is performed at a certain temperature between 300° C. and 500° C., and the silicide layer 108 comprises NiPtSi. The silicide layer 108 can reduce the resistance between the source/drain region 107 and a metal plug 120 (shown in FIG. 15) which will be formed inside the contact via later.

Then, the unreacted metal layer is removed selectively through a wet etching process (for example, using a solution containing sulfuric acid).

Referring to FIG. 15, metal plugs 120 are formed inside the contact vias to contact with the underlying silicide layer 108 at positions corresponding to them. Specifically, a liner may be deposited firstly (not shown in the figures, for example, TiN, TaN, Ta, or Ti); thereafter, a conductive metal layer is deposited (for example, Ti, Al, TiAl, Cu, W, and etc); and then, at last the conductive metal layer is planarized (for example, by CMP). Here, the liner is used to prevent shorts caused by the diffusion of the conductive metal layer into the interlayer dielectric layer 110 during the annealing process.

It should be noted that the ultra-thin BOX layer mentioned in the present invention is a BOX layer having a thickness in the range of 2-15 nm, and the ultra-thin SOI layer is a SOI layer having a thickness in the range of 3-20 nm.

Although the present invention has been disclosed as above with reference to preferred embodiments thereof but will not be limited thereto. Those skilled in the art can modify and vary the embodiments without departing from the spirit and scope of the present invention. Accordingly, the scope of the present invention shall be defined in the appended claims.

1. A MOS transistor, comprising:
an SOI substrate, which comprises a silicon substrate layer, an ultra-thin BOX layer, and an ultra-thin SOI layer;
a metal gate layer formed on the SOI substrate; and
a ground halo region, which is formed within the silicon substrate layer and beneath the metal gate layer.

2. The MOS transistor according to claim 1, wherein the ultra-thin SOI layer has a thickness in the range of 3-20 nm and the ultra-thin BOX layer has a thickness in the range of 2-15 nm.

3. The MOS transistor according to claim 1, further comprising a high-K dielectric layer formed between the metal gate layer and the ultra-thin SOI layer.

4. The MOS transistor according to claim 1, wherein for an n-type MOS transistor, the ground halo region comprises p-type dopants, and for a p-type MOS transistor, the ground halo region comprises n-type dopants.

5. The MOS transistor according to claim 4, wherein the ground halo region has a doping concentration of 1×10¹⁷-3×10¹⁹/cm³.

6. The MOS transistor according to claim 1, further comprising a raised source region and a raised drain region, which are formed on the ultra-thin SOT layer and at opposite sides of the metal gate.

7. The MOS transistor according to claim 6, wherein for a p-type MOS transistor, the raised source region and the raised drain region comprise a SiGe layer, and for an n-type MOS transistor, the raised source region and the raised drain region comprise a Si:C layer.

8. The MOS transistor according to claim 7, wherein for the Si:C layer, the atomic percentage of C is 0.5-2%, and for the SiGe layer the atomic percentage of Ge is 20-70%.

9. The MOS transistor according to claim 7, a her in for an n-type MOS transistor, the Si:C layer further comprises n-type dopants, and for a p-type MOS transistors, the SiGe layer further comprises p-type dopants.

10. The MOS transistor according to claim 4, wherein the p-type dopants comprise B, In, or a combination thereof, and the n-type dopants comprise As, P, or a combination thereof.

11. A method for manufacturing a MOS transistor, comprising:
providing an SOT substrate, the SOT substrate having a silicon substrate layer, ultra-thin BOX layer, and an ultra-thin SOI layer;
forming a dummy gate conductive layer and a plurality of spacers, the plurality of spacers surrounding the dummy gate conductive layer on the SOI substrate;
removing the dummy gate conductive layer to form an opening;
performing an ion-implantation process into the opening to form a ground halo region within the silicon substrate; and
forming a metal gate layer in the opening.

12. The method according to claim 1 wherein the ultra-thin SOT layer has a thickness in the range of 3-20 nm and the ultra-thin BOX layer has a thickness in the range of 2-15 nm.

13. The method to claim 11, further comprising: forming high-K dielectric layer in the opening before the metal gate layer is formed.

14. The method according to claim 11, further comprising: performing an annealing process after the ground halo region is formed.

15. The method according to claim 11, wherein during the formation of the ground halo region, the ion-implantation process is performed with p-type dopants for an n-type MOS transistor, and with n-type dopants for as p-type MOS transistor.

16. The method according to claim 15, wherein the ground halo region has a doping concentration of 1×10¹⁷-3×10¹⁹/cm³.

17. The method according to claim 11, further comprising: forming a raised source region and a raised drain region through a selective epitaxial growth process after the dummy gate conductive layer and the spacers are formed.

18. The method according to claim 17, wherein during the selective epitaxial growth process, a SiGe layer is formed for a p-type MOS transistor, and a Si:C layer is formed for an n-type MOS transistors.

19. The method according to claim 18, wherein for the Si:C layer, the atomic percentage of C is 0.5-2%, and for the SiGe layer, the atomic percentage of Ge is 20-70%.

20. The method according to claim 18, wherein an in-situ doping process is performed with n-type dopants for an n-type MOS transistor, and with p-type dopants for a p-type MOS transistor.

21. The method according to claim 15, wherein the p-type dopants comprise B, In, or a combination thereof, and the n-type dopants comprises As, P, or a combination thereof.
